(19) United States
(12) Patent Application Publication
(10) Pub. No.: US 2022/0361328 A1
(43) Pub. Date: Nov. 10, 2022

(54) POWER CONVERSION MODULE USING CMT CONNECTOR

(71) Applicant: Intel Corporation, Santa Clara, CA (US)

(72) Inventors: Xiang LI, Portland, OR (US); Konika GANGULY, Portland, OR (US); Tongyan ZHAI, Portland, OR (US); George VERGIS, Portland, OR (US); Anthony M. CONSTANTINE, Portland, OR (US); Jun LIAO, Portland, OR (US)

(21) Appl. No.: 17/871,686

(22) Filed: Jul. 22, 2022

Related U.S. Application Data
(60) Provisional application No. 63/348,999, filed on Jun. 3, 2022.

(51) Int. Cl. H05K 1/11; H05K 1/18; G06F 1/18

(52) U.S. Cl. CPC H05K 1/111; H05K 1/181; G06F 1/184

(57) ABSTRACT

Power conversion modules using compression mount technology (CMT) connectors and associated apparatus and methods. Assemblies include a CMT connector that includes an array of spring-loaded CMT pins or contacts that are configured to contact respective pads on a pair of printed circuit board (PCBs), such as for VR module card or power conversion module and a motherboard. The power conversion modules in combination with the CMT connectors provide several advantages, including, a common VR module/power conversion module/motherboard footprint across OEM platforms and test hardware, just in time VR module attachment for improved inventory management, removable power delivery solution makes the platform more conducive to debug, in field servicing, and platform upgradable for higher power CPU/GPU/XPU.

### CLAIM OF PRIORITY

This application claims the benefit of the filing date of U.S. Provisional Application No. 63/348,999, filed Jun. 3, 2022, entitled “POWER CONVERSION MODULE USING CMT CONNECTOR” under 35 U. S.C. § 119(e). U.S. Provisional Application No. 63/348,999 is further incorporated herein in its entirety for all purposes.

### BACKGROUND INFORMATION

Modern computer systems may employ voltage regulator circuits (VRs) and/or voltage regulator modules (VRMs) to regulate the voltage levels supplied to various system components, such as a central processing unit (CPU) or System on a Chip (SoC) including a CPU. FIG. 1 shows two motherboards 100 and 102 illustrating exemplary VR architectures. The VR architecture for motherboard 100 employs multiple discrete VRs, including a system management VR, a CPU core VR, a graphics (Gfx) core VR, and Input-Ouput (IO) VR, a PLL (Phase Lock Loop) VR, and a memory VR. The VR architecture for motherboard 102 employs a Fully Integrated Voltage Regulator (FIVR) on the CPU package or in the CPU die. The FIVR architecture, which may also be referred to as an integrated voltage regulator (IVR) has a single Input VR, along with a memory VR.

Historically, most VR implementations employ one or more VRMs that are directly soldered to the motherboard with a package having a specific pin configuration. The pin configuration is based on voltage input/output, output power rating of the VR, number of distinct voltage output rails, and voltage regulator control requirements. The system OEM (Original Equipment Manufacturer) selects the VR supplier and CPU supplier for a particular platform and designs the motherboard for the exact combination of the two. Once that motherboard is designed, it is used throughout the product service lifetime. During the product service lifetime, if the supply chain is disrupted for the VR company(ies) or CPU company(ies), the OEM is forced to redesign the motherboard, resulting in product discontinuity.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 shows a pair of motherboards employing a conventional VR architecture and a FIVR architecture;

FIG. 2a is a diagram showing a side cross-section view of an assembly including a power conversion module coupled to a motherboard via a compression mount technology (CMT) connector, according to a first embodiment;

FIG. 2b is a diagram showing an end cross-section view of the assembly of FIG. 2a;

FIG. 2c is a diagram showing a side cross-section view of an assembly including a power conversion module with a voltage regulation module (VRM) and associated circuitry mounted to the underside of the printed circuit board (PCB), according to a second embodiment;

FIG. 2d is a diagram showing a side cross-section view of an assembly including a power conversion module with a first VRM and associated circuitry mounted to the topside of the PCB and a second VRM and associated circuitry mounted to the underside of the PCB, according to a third embodiment;

FIG. 2e is a diagram showing a side cross-section view of an assembly illustrating a variant of the assembly of FIG. 2c, further including a heatsink mounted to the topside of the PCB, according to a fourth embodiment;

FIG. 2f is a diagram showing a side cross-section view of an assembly including a power conversion module with a VRM and associated circuitry mounted to the underside of the PCB where the circuitry includes components that extend below the top surface plane of the motherboard, according to a fifth embodiment;

FIG. 2g is a diagram showing a side cross-section view of an assembly including a first VRM and associated circuitry mounted to the topside of the PCB and second power conversion module with a VRM and associated circuitry mounted to the underside of the printed circuit board (PCB) where the circuitry includes components that extend below the top surface plane of the motherboard, according to a fifth embodiment;

FIG. 2h is a diagram showing a side cross-section view of an assembly illustrating a variant of the assembly of FIG. 2h, further including a heatsink mounted to the topside of the PCB, according to a six embodiment;

FIG. 3a is a diagram showing a side cross-section view of an assembly including a power conversion module coupled to a motherboard via a CMT connector using an alternative spring-loaded contact structure, according to one embodiment;

FIG. 3b is a diagram showing an end cross-section view of the assembly of FIG. 3a;

FIG. 4a shows a 3D view of a CMT connector, according to one embodiment

FIG. 4b shows a close-up view of the top of the spring contact structure used for the CMT pins;

FIG. 4c shows a 3D view of a spring contact used for the CMT pins, according to one embodiment;

FIG. 5 is diagram illustrating an example of a VR module card 500;

FIG. 5a is a diagram illustrating an example of a power conversion module including capacitors, inductors, and a controller IC that extend above the board;

FIG. 6 is a diagram illustrating selective components for a platform in which a power conversion module is used to provide power to an SoC, memory, and other platform components, according to one embodiment;

FIG. 7 is a diagram illustrating selective components for a platform in which an SoC power conversion module is used to provide power to an SoC, a memory power conversion module is used to provide power to a memory controller and memory subsystem, and where one or both of the SoC and memory power conversion modules may be used to provide power to other platform components, according to one embodiment;

FIG. 8 is a diagram of a platform employing an SoC/GPU power conversion module that provides power to an SoC and a discrete GPU while employing a memory power conversion module to provide power to a memory controller in the SoC and memory subsystem, and where one or both of the SoC/GPU and memory power conversion modules may be used to provide power to other platform components, according to one embodiment;

FIG. 9 is a diagram of an exemplary compute platform in which embodiments disclosed herein may be implemented.

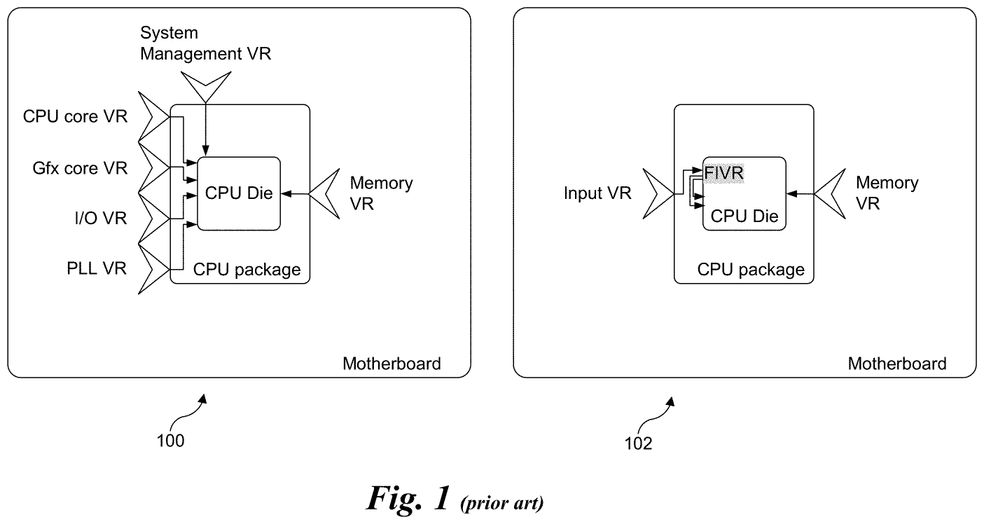

### DETAILED DESCRIPTION

Embodiments of power conversion modules using compression mount technology (CMT) connectors and associated apparatus and methods are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

In accordance with an aspect of the embodiments described and illustrated herein, modularized power conversion and VR solutions are provided. The power conversion modules and VR module cards disclosed herein employ a compression mount technology (CMT) connector that includes dedicated pin locations to support a wide variety of configurations required to support different power conversion and VR suppliers and CPU companies. The power conversion and VR solutions enables a standardized modularized assemblies including a CMT connector to be used across motherboard SKUs for system OEMs and integrators.

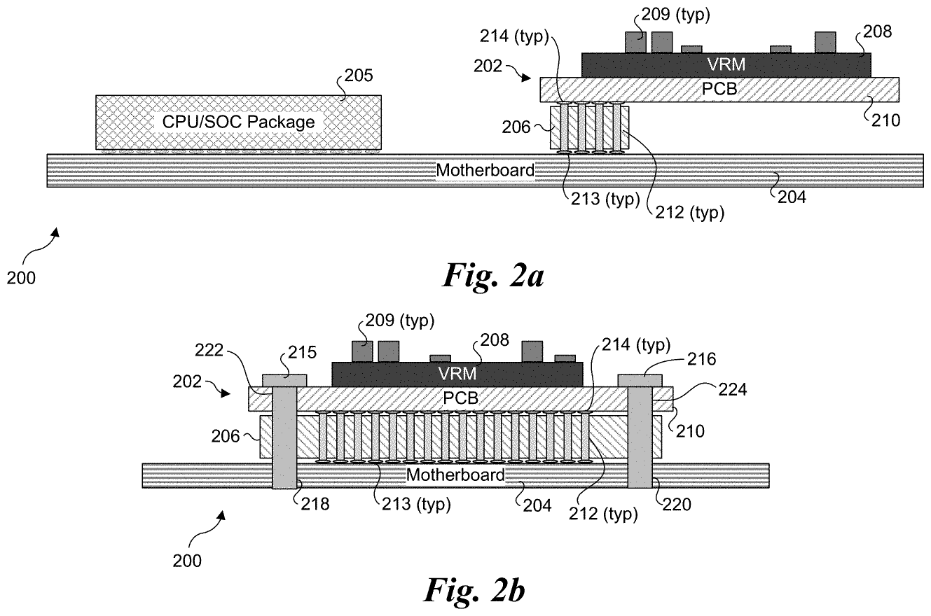

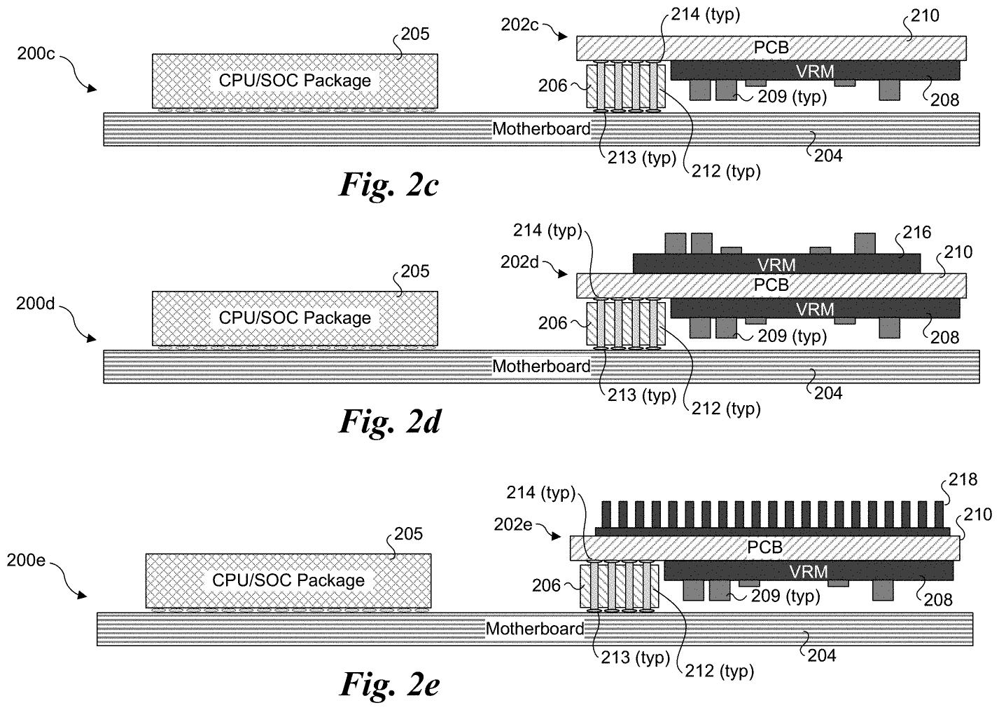

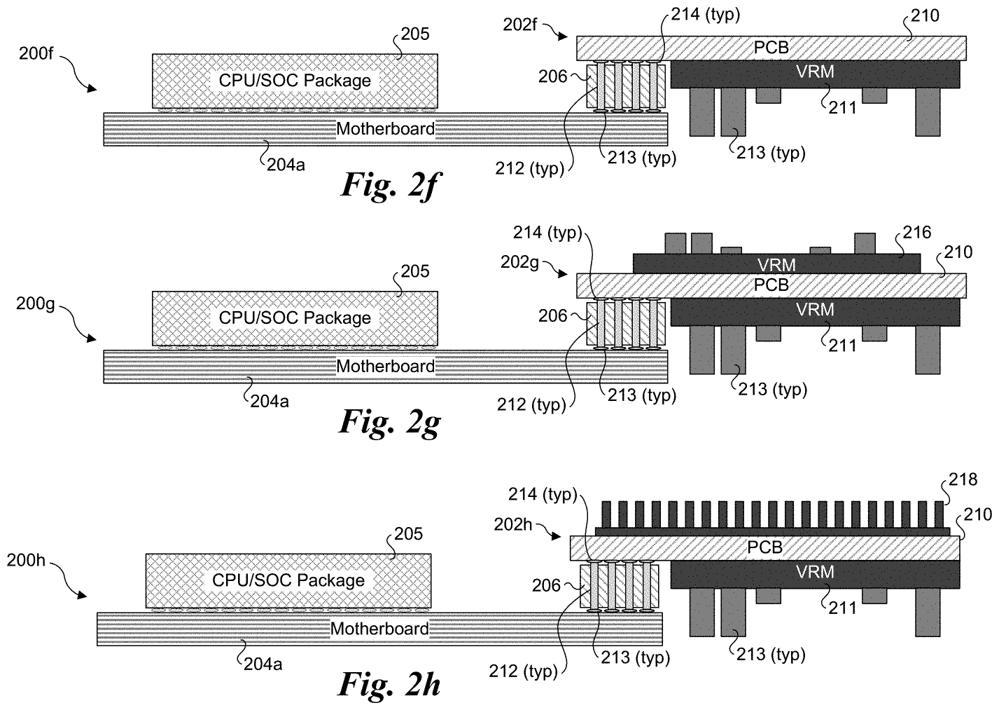

FIG. 2a shows a side cross-section view of an assembly 200 including an VR module card 202 coupled to a motherboard 204 including a CPU or SOC package 205 via a CMT connector 206, while FIG. 2b shows an end cross-section view of the same assembly 200. In the Figures illustrated herein, the vertical dimensions are exaggerated for clarity. Those skilled in the art will recognize the height of the assemblies in practice are substantially less than that shown.

VR module card 202 includes various voltage regulation circuitry and chips collectively depicted as VRM 208 coupled to a PCB 210. In one embodiment, VRM 208 is an encapsulated package or chip coupled to solder pads on the top surface of PCB 210 (not shown) using solder bumps. Other types of packaging technologies may also be used. For illustrative purposes, components labeled “VRM” are shown in some of the Figures herein; however, it shall be recognized that some embodiments may employ discrete power conversion circuitry that does not include a packaged VRM such as VRM 208 and/or a combination of a VRM and discrete power conversion circuitry may be used. Exemplary and non-limiting discrete power conversion circuitry include capacitors and inductors, which are depicted in silhouette as components 209 in FIGS. 2a and 2b.

CMT connector 206 includes an array of CMT pins 212 that are spring-loaded at opposing ends and include lobes that contact respective CMT contact pads 213 on the top layer of motherboard 204 and CMT contact pads 214 on the underside of PCB 210. As shown in FIG. 2b, assembly 200 is coupled together using a pair of screws 215 and 216 that are screwed into respective threads 218 and 220 in motherboard 204. Also, a pair of holes 222 and 224 are formed in PCB 210 having a size that matches the shoulder diameter of screws 215 and 216. Other types of fasteners may also be used as an alternative to screws in some embodiments.

In some platforms, such as laptops, notebooks, Chromebooks, and “all-in-ones,” the overall thickness of the platform is reduced, with the result being there is limited space for power conversion components. This may also be true in some server platforms (e.g., 1U rack chassis, server blades, and server modules). To address this consideration, some embodiments invert some or all the power conversion circuitry such that the orientation of the VR module card or power conversion module board is flipped relative to that shown in FIGS. 2a and 2b. For example, FIGS. 2c-2h show assemblies in which the circuitry for a power conversion module or VR module card extends downward toward the motherboard, with the result being the overall stack height of the assembles are reduced.

Under an assembly 200c shown in FIG. 2c, a VR module card 202c is used that has the power conversion and/or VR module circuitry on the same side as the array of CMT contact pads 214. Generally, the circuitry for VR module cards 202 and 202c may be similar or the same, observing that when a VRM and/or power conversion circuitry is on the opposite side of the CMT contact pads a portion of the VRM/power conversion circuitry may be disposed above the CMT contact pads (such as shown in assembly 200).

Under some circumstances, it may be advantageous to mount VR modules and/or power conversion circuitry to both sides of a VR module card or power conversion module board. An example of such a configuration is shown by an assembly 200d in FIG. 2d, which includes a power conversional module board 202d having a VRM 208 that is mounted to the underside of PCB 210 and a VRM 216 that is mounted to the topside of PCB 210. As before, in addition to or in place of VRMs 208 and 216, a power conversion module board may include discrete power conversion circuitry and associated components. While stack height of assembly 200d is increased relative to assembly 200c, an advantage is that two VRMs and/or two sets of power conversion circuitry occupy the same area for the motherboard's surface plane.

In instances, power conversion circuitry may generate a significant amount of heat. This is due to the fact that power conversion circuitry is not 100% efficient, and may generally generate heat that is approximately proportion to the power output(s) of the circuitry (observing this heat generation portion may have a non-linear relationship). To address this issue, a VR module card or power conversion module board may include a heatsink, such as shown by a heatsink 218 in an assembly 200e illustrated in FIG. 2e. Generally, heatsink 218 is illustrative of a variety of types of heatsinks and/or heat dissipation components, including those employing some form of liquid cooling.

A way to further reduce the stack height for embodiments employing power conversion circuitry with a moderate to tall stack height is to have the power conversion module extending downward past the top surface plane of the motherboard, such as shown in the embodiments of FIGS. 2f, 2g, and 2h. From a plan (i.e., top) view, the motherboard may have a cutout to accommodate the extended through circuit components, or the power conversion module circuitry may extend past a motherboard.

Assembly 200f shown in FIG. 2f includes a power conversion module board 202f having a VRM 211 and/or discrete power conversion circuitry including one or more components 213 having a height the extends below the top surface plane of motherboard 204a. Assembly 200g in FIG. 2g includes a power conversion module board 202g that is similar to power conversion module board 202d, except components 213 are taller than components 209. Likewise, a power conversion module board 202h in assembly 200h of FIG. 2h is similar to power conversion module board 202e shown in FIG. 2e except components 213 are taller than components 209. In addition to the configurations illustrated herein, power conversion modules may be stacked in other embodiments that are not separately illustrated.

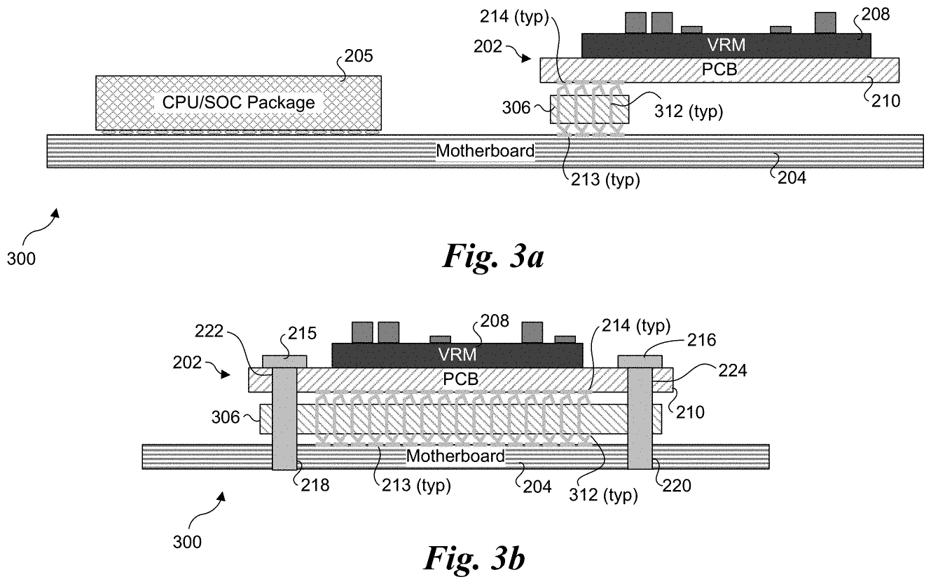

FIGS. 3a and 3b respectively show a side cross-section view and an end cross-section view of an assembly 300 that employs a CMT connector 306 in place of CMT connector 206. Components with like-numbered references in assemblies 200 and 300 are similar in both embodiments. For CMT connector 306, the spring-loaded pins 212 are replaced with spring-loaded contacts 312. Generally, CMT connector 306 may be used in place of CMT connector 206 in any of the embodiments shown herein.

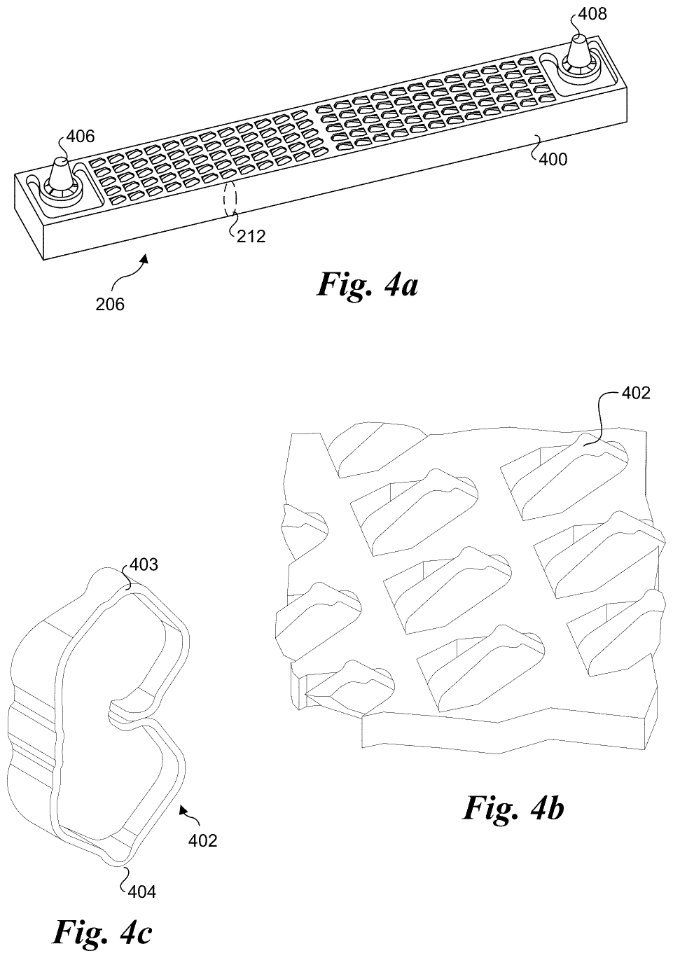

FIG. 4a shows a 3D view of a CMT connector 206, according to one embodiment. CMT connector 206 includes a body 200 in which arrays of CMT pins 212 are installed. As shown in FIGS. 4b and 4c, the CMT pins include a pair of spring contacts that are installed in opposing ends of tubes that are compressed when CMT connector 206 is installed in assembly 200. As shown in FIG. 4c, a spring contact 402 comprises a bent structure made of a suitable metal and includes a pair of lobes 403 and 404; when two spring contacts 402 are installed in a tube and the components of assembly 200 are assembled, lobe 403 will contact a contact pad 214 on VR module card 202 while lobe 404 will contact a contact pad 213 on motherboard 204. The tubes are disposed in respective holes in body 200, and the spring contacts 402 are inserted into the opposing ends of the tubes. CMT connector 206 further includes a pair of fasteners 406 and 408 (e.g., screws).

For CMT connector 306 shown in FIGS. 3a and 3b, CMT contacts 312 comprise a single member made of a suitable metal. The CMT contacts may be embedded in the body of CMT connector 306 when formed, or inserted into suitable holes or apertures formed in the CMT connector body during a separate manufacturing operation.

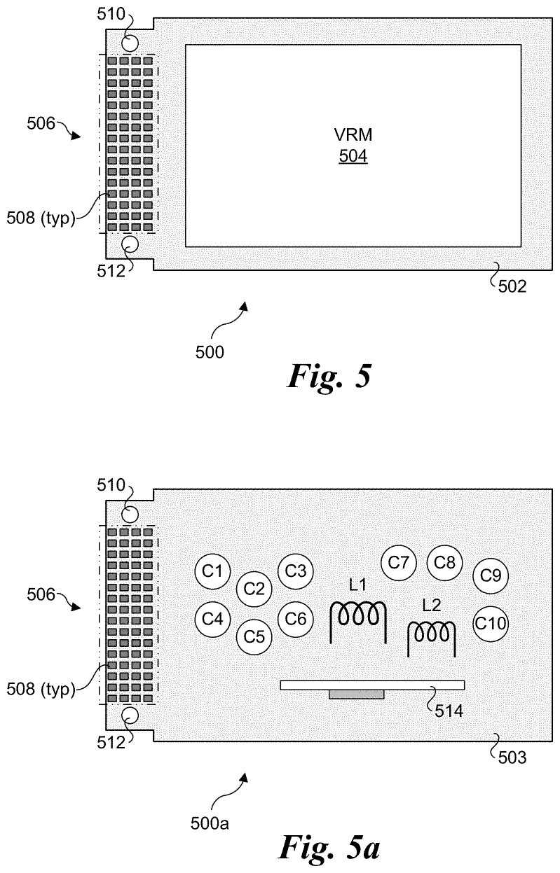

FIG. 5 shows an example of a VR module card 500. VR module card 500 includes a PCB 502 to which various voltage regulation circuitry and components are mounted, collectively depicted as a VRM 504. PCB 502 also includes an array 506 of pads 508. In some embodiments, the pads 508 in the array are formed on the side of the PCB that is opposite the CMT connector when the VR module card is installed, while in other embodiments, pads 508 and VRM 504 are on the same side. PCB 502 also includes alignment holes 510 and 512 in which a pair of screws would be inserted, with the diameter of the alignment holes matching the diameter of the shoulders of the screws.

Signal traces (e.g., wiring) in PCB 502 are used to provide signal paths between pads 508 and voltage regulation circuitry and components in VRM 504. Upon installation of VR module card 500 in a platform (e.g., desktop computer, server, laptop, notebook computer, all-in-one, etc.), pads 508 are electrically coupled to respective pins 212 or contacts 312 in the CMT connector (206 or 306), which in turn are coupled to CMT contact pads 213 on motherboard 204.

FIG. 5a shows a power conversion module 500a in which power conversion circuitry and associated components are mounted to a board 503. The associated components include capacitors C1-C10, a pair of inductors L1 and L2, and a control logic board or chip 514. Generally, the difference between the VR module cards and the power conversion modules illustrated herein is that a VRM is a single component or package having a low profile, while a power conversion module may include circuit components that are discrete components that are generally taller than a VRM. It will be recognized by those skilled in the art that a VR module card will have additional circuitry besides a VRM, and that a power conversion module will have additional circuitry and components beyond those depicted in FIG. 5a.

The number of pads, dimensions of the array, size of the pads, and pitch are all parameters that may be varied to suit the needs of a given platform. This enables support for a larger number of configurations and increases flexibility. In one embodiment, the array of pads will include pads with standardized voltage levels and control pin assignment, allowing the platform to connect to the appropriate pins as required.

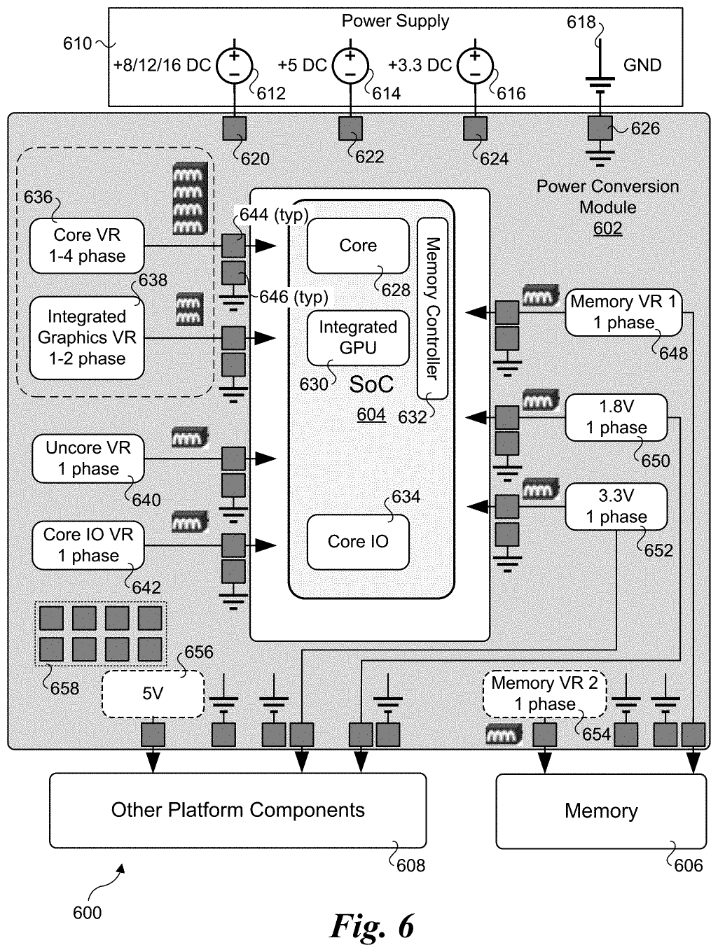

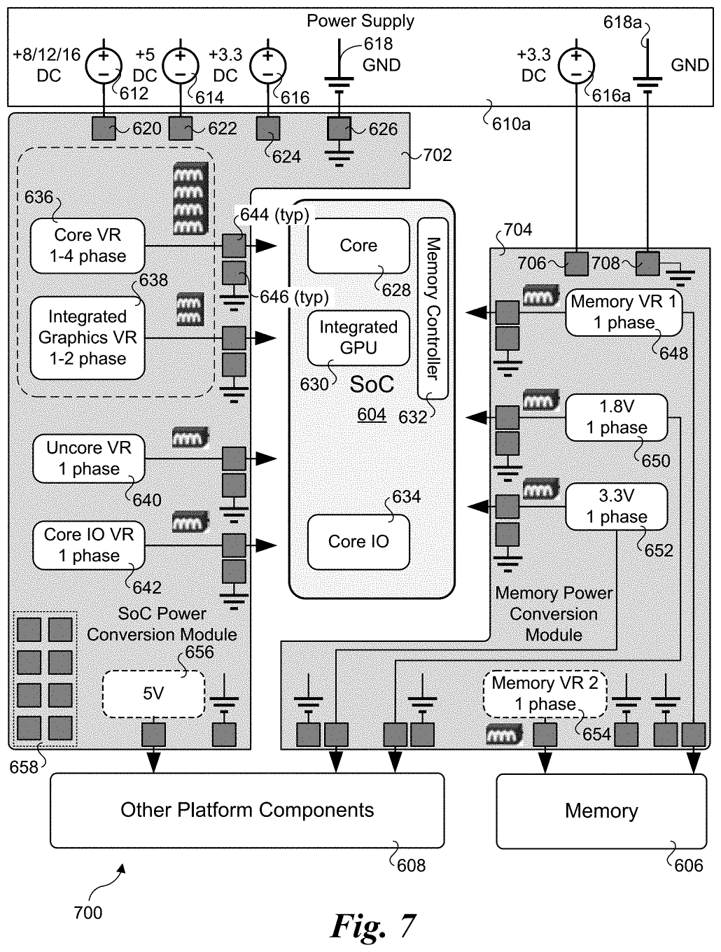

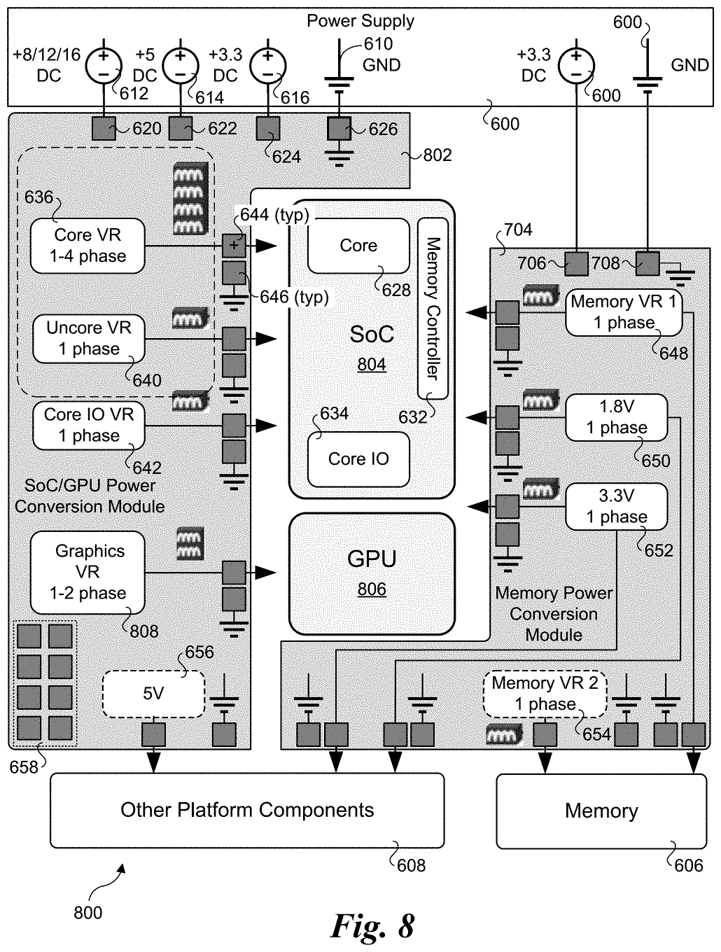

FIG. 6 is a diagram illustrating selective components for a platform 600 in which a power conversion module 602 is used to provide power to an SoC 604, memory 606, and other platform components 608, according to one embodiment. A power supply 610 provides input voltages and grounds to power conversion module 602, as depicted by a +8/12/16 volt (V) DC input 612, a +5V DC input 614, a +3.3V DC input 616, and a ground input 618. Each of these input voltages will be received at one or more CMT contact pads on the power conversion module board, as depicted by CMT contact pads 620, 622, 624, and ground CMT contact pad 626. In practice, each input voltage provided by a power supply will generally be supplied at multiple CMT contact pads on a power conversion module; for simplicity, only single CMT contact pads are shown in platform 600 and platforms 700 and 800 of FIGS. 7 and 8 described and illustrated below. Generally, a power supply may be mounted or operatively coupled to a motherboard (e.g., using a power connector), and the motherboard will include wiring to route various voltages and grounds to CMT contact pads on the motherboard that are opposite of CMT contact pads on a power conversion module board. However, for illustrative purposes, the power supply input voltages are shown directly coupled to CMT contact pads 620, 622, 624 and ground CMT contact pad 626.

SoC 604 is illustrative of a processor SoC including a core 628, an integrated GPU 630, memory controller 632, and a core IO (input-output) block 634. In addition, circuitry and blocks that are separate from these blocks is generally referred to as “uncore” circuitry and blocks. Core 628, which may be referred to as a CPU core when SoC 604 includes a CPU includes one or more processor/CPU cores. Core 628 may also include cache levels associated with the processor/CPU cores, such as Level 1 and Level 2 (L1 and L2) caches (not shown). In some embodiments, an L3 or last level cache (LLC) (not shown) may be shared across processor/CPU cores.

Integrated GPU 630 is illustrative of an SoC that includes integrated graphics circuitry, such as but not limited to a GPU. The integrated GPU may be implemented using a variety of GPU architectures and may support various graphics and/or accelerator libraries, including open-source and proprietary libraries.

Core IO block 634 is illustrative of various IO components and or blocks that are included in an SoC. For example, the IO components may support standardized and/or propriety IO interfaces and protocols, such as but not limited to Peripheral Component Interconnect Express (PCIe) and Compute Express Link (CXL) interfaces and protocols. Other IO interfaces may also be supported.

As further shown in FIG. 6, power conversion module 602 provides various regulated input voltages and grounds to components in SoC 604. A first portion of these are regulated input voltages and grounds are depicted by a core VR input 636, an integrated graphics VR rail 638, an uncore VR input 640, and a core IO VR input 642. The + voltage inputs (also known as voltage rails) are shown as being provided at a + voltage rail CMT contact pad 644, with a corresponding ground being shown as being provided at a ground CMT contact pad 644. In practice, a given + voltage input corresponding to a given voltage rail may be provided at multiple CMT contact pads. For illustrative purposes, a + voltage rail CMT contact pad 644 and a ground CMT contact pad are shown on a pairwise basis; however, it will be recognized that these may be separated (for example, multiple + voltage rail CMT pads and/or multiple ground CMT contact pads may be grouped together.

Core VR input 636 is shown as supporting 1-4 phases. For supply voltages, multiple phases may be combined to provide additional voltage levels. For example, depending on the workload for the cores in core 628, a variably amount of regulated voltage may be provided, with the increase in voltages resulting in higher performance, higher energy consumption, and greater heat generation (by SoC 604). In some embodiments, one or more cores in core 628 may support a boosted performance mode such as a so-called “turbo” mode under which the core is operated at a higher voltage. It will also be recognized that a processor or CPU may employ different types of cores, such as a mixture of higher power, higher performance cores and lower power, lower performance cores. Although shown as a single power input for convenience, core VR input 636 may provided different voltage level inputs to be used by different cores.

In the illustrated embodiment, integrated graphics VR input also is a multi-phase input (in this non-limiting example 1-2 phases). Like processor/CPU cores, a GPU may operate at different performance levels based on its input voltage, which may be varied by using 1 or 2 phases. In some embodiments, additional phases may be provided.

As further shown, both uncore VR input 640 and core IO VR input are single phase inputs. Generally, the uncore and IO circuitry may operate in a power domain that is separate from that employed by the processor/CPU cores and GPU and consume less power.

Additional voltage inputs provided by power conversion module 602 include memory VR 2 input 648, 1.8V input 650, and 3.3V input 652. Memory VR 1 input 648 is used to support memory subsystem components including memory controller 632 and memory 606, which is representative of one or more memory devices and associated memory buses/channels. Although SoC 604 shows a single memory controller 632, a given SoC may include one or more memory controllers (which are sometimes referred to as integrated memory controllers or IMCs). As further shown, one or both of 1.8V input 650, and 3.3V input 652 may be used to provide input to other platform components 608, which are representative of various platform components that are separate from the platform SoC and memory subsystem.

Power conversion module 602 further shows two optional voltage inputs: a memory VR 2 input 654 and a 5V input 656. Memory VR 2 input 654 may be used to provide additional power to memory 606. Generally, 5V input 656 may provide input to other platform components that may employ a 5V input voltage.

A power conversion module may also provide additional signals to one or more components, such as but not limited to signals for a CPU, GPU, XPU, SoC, and/or other platform component. For example, additional signals may include signaling for power state monitoring, power state control, and signaling supporting communication with various IO components. Under one non-limiting example, additional signals may be employed to enable communication between the power conversion module and the CPU/SoC and an embedded controller (EC), such as for standby mode enable, putting the CPU/SoC into a deep sleep mode and for power gating etc. A CPU/SoC cores may support a “turbo” or “boost” mode under which the CPU/SoC operates one or more cores at a higher frequency requiring increased input voltage—the additional signals may be used to support CPU/SoC and EC communication with the power conversion module to change its input voltage(s).

For simplicity and lack of space, the CMT contact pads for these additional signals are shown in the Figures herein including FIG. 6 as other CMT contact pads 658. These contact pads would be connected to pads and/or pins on applicable components via a CMT connector and wiring in the motherboard and other wiring/connectors, such as in a CPU or SoC package, interposer, etc.

FIG. 7 shows a platform 700 employing an SoC power conversion module 702 and a memory power conversion module 704. As shown by the same reference numbers, the components and circuitry for SoC power conversion module 702 and a memory power conversion module 704 are similar to those for power conversion module 602, except two power conversion modules are used rather than one. Each of SoC power conversion module 702 and a memory power conversion module 704 will have its own set of CMT contact pads. As shown in FIGS. 7 and 8, in addition to the DC voltages and ground provided by power supply 610, a power supply 610a further provides a +3.3V DC input 616a and a ground 618a that are respective received at CMT contact pads 658 and 660. Those skilled in the art will recognize that +3.3V DC inputs 616 and 616a may be provided by the same power supply circuitry or separate circuitry and that grounds 618 and 618a would have a common (ground) voltage level.

FIG. 8 shows a platform 800 employing an SoC/GPU power conversion module 802 that provides input voltages to an SoC 804 and a separate GPU 806. Platform 800 also includes a memory power conversion module 704. As shown by the same reference numbers, the components and circuitry for SoC/GPU power conversion module 802 and SoC/GPU power conversion module 702 are similar, except in this embodiment the SoC and GPU are separate components. Accordingly, SoC/GPU power conversion module 802 includes a graphics VR input 808 that is provided to GPU 806 (via applicable CMT contact pads and CMT contacts or pins). As an alternative to the two power conversion module configuration of platform 800, a single power conversion module may be used to supply power to a platform including a separate SoC and GPU.

Example Compute Platform

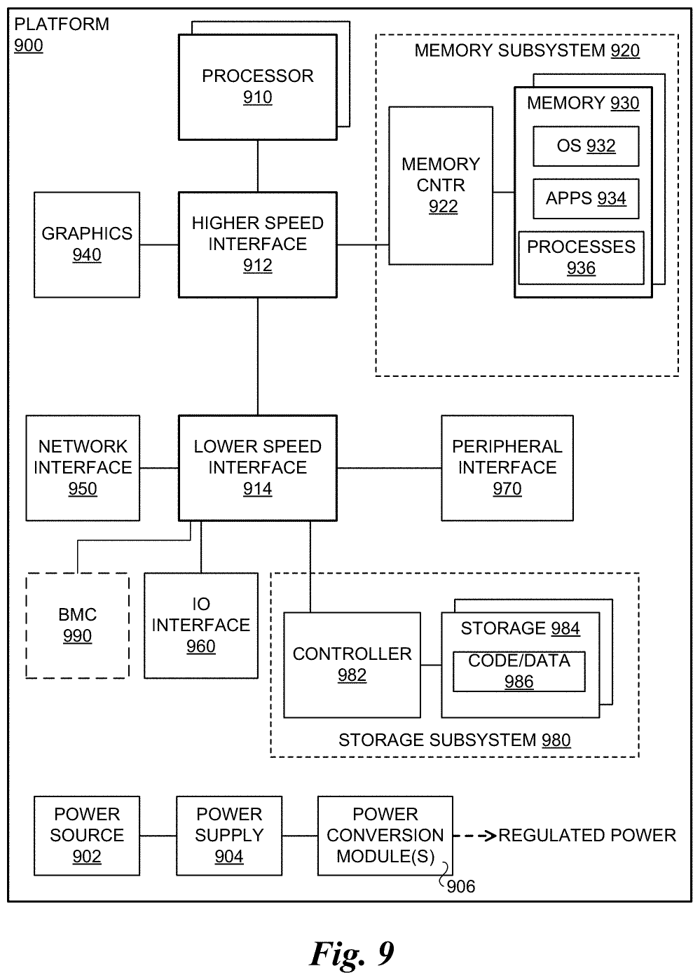

FIG. 9 illustrates an example compute platform 900 in which aspects of the embodiments may be practiced. Generally, compute platform 900 shows additional component relative to platforms 600, 700, and 800. Compute platform 900 represents a computing device or computing system in accordance with any example described herein, and can be a server, laptop/notebook computer, all-in-one, desktop computer, or the like. More generally, compute platform 900 is representative of any type of computing device or system employing one or more power conversion modules and/or VR module cards.

Compute platform 900 includes a processor 910, which provides processing, operation management, and execution of instructions for compute platform 900. Processor 910 can include any type of microprocessor, central processing unit (CPU), graphics processing unit (GPU), processing core, or other processing hardware to provide processing for compute platform 900, or a combination of processors. Processor 910 controls the overall operation of compute platform 900, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, compute platform 900 includes interface 912 coupled to processor 910, which can represent a higher speed interface or a high throughput interface for system components that needs higher bandwidth connections, such as memory subsystem 920 or graphics interface components 940. Interface 912 represents an interface circuit, which can be a standalone component or integrated onto a processor die. Where present, graphics interface 940 interfaces to graphics components for providing a visual display to a user of compute platform 900. In one example, graphics interface 940 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 940 generates a display based on data stored in memory 930 or based on operations executed by processor 910 or both.

Memory subsystem 920 represents the main memory of compute platform 900 and provides storage for code to be executed by processor 910, or data values to be used in executing a routine. Memory 930 of memory subsystem 920 may include one or more memory devices such as DRAM DIMMs, read-only memory (ROM), flash memory, or other memory devices, or a combination of such devices. Memory 930 stores and hosts, among other things, operating system (OS) 932 to provide a software platform for execution of instructions in compute platform 900. Additionally, applications 934 can execute on the software platform of OS 932 from memory 930. Applications 934 represent programs that have their own operational logic to perform execution of one or more functions. Processes 936 represent agents or routines that provide auxiliary functions to OS 932 or one or more applications 934 or a combination. OS 932, applications 934, and processes 936 provide software logic to provide functions for compute platform 900. In one example, memory subsystem 920 includes memory controller 922, which is a memory controller to generate and issue commands to memory 930. It will be understood that memory controller 922 could be a physical part of processor 910 or a physical part of interface 912. For example, memory controller 922 can be an integrated memory controller, integrated onto a circuit with processor 910.

While not specifically illustrated, it will be understood that compute platform 900 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus.

In one example, compute platform 900 includes interface 914, which can be coupled to interface 912. Interface 914 can be a lower speed interface than interface 912. In one example, interface 914 represents an interface circuit, which can include standalone components and integrated circuitry. In one example, multiple user interface components or peripheral components, or both, couple to interface 914. Network interface 950 provides compute platform 900 the ability to communicate with remote devices (e.g., servers or other computing devices) over one or more networks. Network interface 950 can include an Ethernet adapter, wireless interconnection components, cellular network interconnection components, USB (universal serial bus), or other wired or wireless standards-based or proprietary interfaces. Network interface 950 can exchange data with a remote device, which can include sending data stored in memory or receiving data to be stored in memory.

In one example, compute platform 900 includes one or more IO interface(s) 960. IO interface(s) 960 can include one or more interface components through which a user interacts with compute platform 900 (e.g., audio, alphanumeric, tactile/touch, or other interfacing). Peripheral interface 970 can include any hardware interface not specifically mentioned above. Peripherals refer generally to devices that connect dependently to compute platform 900. A dependent connection is one where compute platform 900 provides the software platform or hardware platform or both on which operation executes, and with which a user interacts.

In one example, compute platform 900 includes storage subsystem 980 to store data in a nonvolatile manner. In one example, in certain system implementations, at least certain components of storage subsystem 980 can overlap with components of memory subsystem 920. Storage subsystem 980 includes storage device(s) 984, which can be or include any conventional medium for storing large amounts of data in a nonvolatile manner, such as one or more magnetic, solid state, or optical based disks, or a combination. Storage device(s) 984 holds code or instructions and data 986 in a persistent state (i.e., the value is retained despite interruption of power to compute platform 900). A portion of the code or instructions may comprise platform firmware that is executed on processor 910. Storage device(s) 984 can be generically considered to be a “memory,” although memory 930 is typically the executing or operating memory to provide instructions to processor 910. Whereas storage device(s) 984 is nonvolatile, memory 930 can include volatile memory (i.e., the value or state of the data is indeterminate if power is interrupted to compute platform 900). In one example, storage subsystem 980 includes controller 982 to interface with storage device(s) 984. In one example controller 982 is a physical part of interface 914 or processor 910 or can include circuits or logic in both processor 910 and interface 914. In one example, a storage device 984 may comprise an AIC such as an NVMe SSD that is mounted to the motherboard using a CMT connector using the assemble architecture shows in the Figures herein and discussed above.

Compute platform 900 may include an optional Baseboard Management Controller (BMC) 990 that is configured to effect the operations and logic corresponding to the flowcharts disclosed herein. BMC 990 may include a microcontroller or other type of processing element such as a processor core, engine or micro-engine, that is used to execute instructions to effect functionality performed by the BMC. Optionally, another management component (standalone or comprising embedded logic that is part of another component) may be used.

Power source 902 provides power to the components of compute platform 900. More specifically, power source 902 typically interfaces to one or multiple power supplies 904 in compute platform 900 to provide power to the components of compute platform 900. Power a power supply 904 provides input power to one or more power conversion modules 906 (and/or VR module card(s)), which provides regulated power to one or more platform components including processor 910. In one example, power supply 904 includes an AC to DC (alternating current to direct current) adapter to plug into a wall outlet. Such AC power can be renewable energy (e.g., solar power) power source 902. In one example, power source 902 includes a DC power source, such as an external AC to DC converter. In one example, power source 902 can include an internal battery or fuel cell source.

Generally, in addition to solutions for providing regulated power to CPUs, the teaching and principles disclosed herein may be applied to Other Processing Units (collectively termed XPUs) including one or more of Graphic Processor Units (GPUs) or General Purpose GPUs (GP-GPUs), Tensor Processing Units (TPUs), Data Processor Units (DPUs), Infrastructure Processing Units (IPUs), Artificial Intelligence (AI) processors or AI inference units and/or other accelerators, Vision Processing Units (VPUs), FPGAs and/or other programmable logic (used for compute purposes), etc. While some of the diagrams herein show the use of CPUs, this is merely exemplary and non-limiting. Generally, any type of XPU may be used in place of a CPU in the illustrated embodiments. Moreover, as used in the following claims, the term “processor” is used to generically cover CPUs, GPUs, and various forms of other XPUs.

The VR module card solutions and power conversion module solutions described and illustrated herein provide several advantages over current approaches. These include:
A common VR module/power conversion module/motherboard footprint across OEM platforms and test hardware
Just in time VR module or power conversion module attachment for improved inventory management
A removable power delivery solution makes the platform more conducive to debug, and in field servicing
Platform upgradable for higher power CPU/GPU/XPU

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. An apparatus, comprising:
a board including voltage regulation circuitry providing a plurality of output voltages, the board further including an array of contact mount technology (CMT) contact pads having a first pattern and disposed on a surface layer of the board and including wiring connecting CMT pads to the plurality of output voltages,
wherein the board is configured to be installed in a compute platform including a CMT connector coupled to a motherboard and having an array of spring-loaded contacts arranged in a second pattern matching the first pattern, and wherein when the board is installed in the compute platform the CMT connector is disposed between the motherboard and the board and the spring-loaded contacts are in compression contact with respective CMT contact pads.

2. The apparatus of claim 1, wherein the voltage regulation circuitry includes at least one voltage regulation module (VRM).

3. The apparatus of claim 1, wherein at least a portion of the voltage regulation circuitry comprises electrical components mounted to the board on a side opposite the array of CMT contact pads.

4. The apparatus of claim 1, wherein at least a portion of the voltage regulation circuitry comprises electrical components mounted to the board on the same side as the array of CMT contact pads.

5. The apparatus of claim 1, wherein a first portion of the voltage regulation circuitry comprises electrical components mounted to the board on a first side and a second portion of the voltage regulation circuitry comprises electrical components mounted to the board on a second side.

6. The apparatus of claim 1, wherein the voltage regulation circuitry comprises electrical components mounted to the board on the same side as the array of CMT contact pads, further comprising a heat sink mounted on the opposite side of the board.

7. The apparatus of claim 1, wherein the plurality of output voltages including output voltages having different phases, and wherein the apparatus is configured to work with a plurality of different motherboards having different input voltage and phase requirements.

8. A compute platform, comprising:
a power conversion module comprising a board having voltage regulation circuitry providing a plurality of output voltages including output voltages having different phases, the board further including a first array of contact mount technology (CMT) contact pads having a first pattern and disposed on a surface layer of the board and including wiring connecting CMT pads to the plurality of output voltages;
a motherboard, including a plurality of components operatively coupled thereto including at least one processor; and
a CMT connector operatively coupled to the motherboard, having an array of spring-loaded contacts or pins arranged in a second pattern matching the first pattern, the CMT connector disposed between the motherboard and the board with the spring-loaded contacts or pins being in compression contact with respective CMT contact pads in the first array of CMT contact pads.

9. The compute platform of claim 8, further comprising a second array of CMT contact pads disposed on a surface layer of the motherboard, the second array of CMT contact pads arranged in a third pattern matching the first pattern, wherein at least a portion of the CMT contact pads in the second array of CMT contact pads are coupled to pins or contacts on the processor via wiring in the motherboard.

10. The compute platform, wherein the spring-loaded contacts or pins include or are operatively coupled to conductive members extending downward below the CMT connector, and wherein the CMT connector is coupled to the motherboard via an array of solder balls that are formed around the conductive members.

11. The compute platform of claim 8, wherein the at least one processor includes a System on a Chip (SoC) including a multi-core central processing unit (CPU) and an integrated graphics processing unit (GPU).

12. The compute platform of claim 8, further comprising:
a second power conversion module comprising a second board having voltage regulation circuitry providing a second plurality of output voltages, the second board including a third array of CMT contact pads having a third pattern and disposed on a surface layer of the second board and including wiring connecting CMT pads to the second plurality of output voltages; and
a second CMT connector operatively coupled to the motherboard, having a second array of spring-loaded contacts or pins arranged in a fourth pattern matching the third pattern, the second CMT connector disposed between the motherboard and the second board with the spring-loaded contacts or pins being in compression contact with respective CMT contact pads in the third array of CMT contact pads.

13. The compute platform of claim 12, wherein the compute platform includes a memory subsystem, and wherein the second power conversion module supplies power to components in the memory subsystem.

14. The compute platform of 8, wherein the CMT connector is disposed toward an edge of the motherboard, and wherein the power conversion module includes voltage regulation circuitry that is disposed on the same side as the first array of CMT contact pads, and wherein the voltage regulation circuitry includes one or more components that extend past a top surface plane of the motherboard:

15. A compute platform, comprising:
a power conversion module comprising a board having voltage regulation circuitry providing a plurality of output voltages including output voltages having different phases, the board further including a first array of contact mount technology (CMT) contact pads having a first pattern and disposed on a surface layer of the board and including wiring connecting CMT pads to the plurality of output voltages;
a motherboard, including a plurality of components operatively coupled thereto including at least a central processing unit (CPU) and a graphics processing unit (GPU)
a CMT connector operatively coupled to the motherboard, having an array of spring-loaded contacts or pins arranged in a second pattern matching the first pattern, the CMT connector disposed between the motherboard and the board with the spring-loaded contacts or pins being in compression contact with respective CMT contact pads in the first array of CMT contact pads,
wherein at least of portion of the plurality of output voltages provided by the power conversion module are used as input voltages for the CPU and the GPU.

16. The compute platform of claim 1, wherein the CPU comprises a System on a Chip including a CPU core, and the plurality of output voltages includes output voltages at multiple phases to power the CPU core.

17. The compute platform of claim 1, further comprising:
a second power conversion module comprising a second board having voltage regulation circuitry providing a second plurality of output voltages, the second board including a third array of CMT contact pads having a third pattern and disposed on a surface layer of the second board and including wiring connecting CMT pads to the second plurality of output voltages; and
a second CMT connector operatively coupled to the motherboard, having a second array of spring-loaded contacts or pins arranged in a fourth pattern matching the third pattern, the second CMT connector disposed between the motherboard and the second board with the spring-loaded contacts or pins being in compression contact with respective CMT contact pads in the third array of CMT contact pads.

18. The compute platform of claim 17, wherein the CPU comprises a System on a Chip (SoC) including a memory controller that is coupled to one or more memory devices, and wherein the second power conversion module provides input power to a memory controller and the one or more memory devices.

19. The compute platform of claim 18, wherein the second power conversion module further provides power to other platform components using at least one of a 1.8 volt output voltage and a 3.3 volt output voltage.

20. The compute platform of claim 15, further comprising a power supply providing a plurality of output voltages and being operatively coupled to the motherboard, wherein the motherboard includes wiring mean for coupling the plurality of power supply output voltages to spring-loaded contacts or pins in the array of spring-loaded contacts or pins arranged in a second pattern matching the first pattern
